(19) United States
(12) Patent Application Publication
(10) Pub. No.: US 2026/0173672 A1
(43) Pub. Date: Jun. 18, 2026

(54) Display Device

(71) Applicant: LG Display Co., Ltd., Seoul (KR)

(72) Inventor: Taehyung Kim, Paju-si (KR)

(21) Appl. No.: 19/372,853

(22) Filed: Oct. 29, 2025

(30) Foreign Application Priority Data
Dec. 12, 2024 (KR) 10-2024-0184546

(51) Int. Cl. H10K 59/124

(52) U.S. Cl. CPC H10K 59/124

(57) ABSTRACT

There is disclosed a display device including a display panel comprising a short side extending along a first direction, a long side extending along a second direction, and a corner at which the short side and the long side meet; and a mold part comprising a first mold part provided on the short side, a second mold part provided on the long side, and a third mold part provided at the corner, and a first pattern that recesses the third mold part from the lower surface of the third mold part may be disposed in the third mold part.

This application claims priority to and the benefit of Korean Patent Application No. 10-2024-0184546, filed on December 12, 2024, the disclosure of which is incorporated herein by reference in its entirety.

### BACKGROUND

### Technical Field

Embodiments of the present disclosure relate to a display device.

### Background of the Disclosure

As the information society develops, various demands for display devices that display images are increasing and various types of display devices, such as liquid crystal displays and organic light emitting diode displays, are being used.

A display device may include a plurality of pixels and a plurality of switching elements configured to drive and control the pixels.

### SUMMARY

Accordingly, one object of embodiments of the present disclosure is to solve the above-noted disadvantages of the prior art, and embodiments of the present disclosure may provide a display device that may reduce the shock transmitted from a mold when the display device is dropped or subjected to external shock.

Another object of the embodiments is to provide a display device that may reduce the stress applied to a mold in a high temperature environment.

Aspects according to the present disclosure are not limited to the above ones, and other aspects and advantages that are not mentioned above can be clearly understood from the following description and can be more clearly understood from the embodiments set forth herein.

To solve the objects of the present disclosure, a display device according to one embodiment of the present disclosure may include The display device according to the embodiments may include a display panel comprising a short side extending along a first direction, a long side extending along a second direction, and a corner at which the short side and the long side meet; and a mold part comprising a first mold part provided on the short side, a second mold part provided on the long side, and a third mold part provided at the corner. A first pattern that recesses the third mold part from the lower surface of the third mold part may be disposed in the third mold part.

In another aspect a display device according to the embodiments of the present disclosure may include a display panel comprising a main-region, a sub-region overlapping the main-region, and a bending region between the main-region and the sub-region; a mold part provided on the outside of the display panel; and a cover layer on the display play. A pattern may be disposed in the mold part on at least one of a plurality of sides and a plurality of corners of the display panel, and the pattern may overlap the cover layer.

Specific descriptions of other embodiments are provided in detailed description and the accompanying drawings.

According to the embodiments of the present disclosure, the third mold part provided at the corner of the display panel may include the first pattern, thereby reducing the shock transmitted from the mold when the display device is dropped or subjected to external shock.

Furthermore, in the display device according to the embodiments of the present disclosure, the mold parts provided on the upper, lower, left, and right sides of the display panel may include the patterns, thereby reducing the shock transmitted from the mold when the display device is dropped or subject to external shock.

Still further, in the display device according to the embodiments of the present disclosure, the third mold part provided at the corner of the display panel may include the first pattern, thereby alleviating stress concentration in the mold part in a high-temperature environment.

Still further, in the display device according to the embodiments of the present disclosure, life span may be improved by reducing shock and alleviating stress.

In addition to the above-described effects, specific effects of the present invention will be described together with the following detailed description for implementing the present invention.

### BRIEF DESCRIPTION OF THE DRAWINGS

FIG. 1 is a plan view showing a display device according to one embodiment;

FIG. 2 is a cross-sectional view showing the state where a display shown in FIG. 1 is bent;

FIG. 3 is a plan view showing the state where a display shown in FIG. 1 is bent;

FIG. 4 is a plan view of a mold part shown in FIG. 3;

FIG. 5 is a cross-sectional view cut along A-A’ of FIG. 3;

FIG. 6 is a cross-sectional view cut along B-B’ of FIG. 3;

FIG. 7 is a cross-sectional view cut along C-C’ of FIG. 3;

FIG. 8 is a cross-sectional view cut along D-D’ of FIG. 3

FIG. 9 is a illustrates a display device according to one embodiment being dropped;

FIG. 10 is a plan view of a mold part according to one embodiment;

FIG. 11 is a graph showing that the shock of the display device is improved;

FIG. 12 is a plan view of a mold part according to another embodiment;

FIG. 13 is a cross-sectional view of a display device according to another embodiment;

FIG. 14 is a plan view of a mold part according to still another embodiment; and

FIG. 15 is a plan view of a mold part according to a still another embodiment.

### DESCRIPTION OF SPECIFIC EMBODIMENTS

Hereinafter, a display device according to embodiments of the present disclosure will be described, referring to the accompanying drawings.

Below, preferred embodiments according to the disclosure are specifically described with reference to the accompanying drawings. In the drawings, identical reference numerals can denote identical or similar components.

It will be understood that when an element is referred to as being “connected with”, “on” or “coupled to” another element, the element can be directly connected with the other element or intervening elements may also be present. In contrast, when an element is referred to as being “directly connected with” another element, there are no intervening elements present.

“And/or” includes any combination of one or more of the associated elements that can be defined.

Terminologies such as “under,” “below,” “on,” “above,” and etc. are used to describe location relationship between the elements shown in the drawings. Such terminologies are relative concepts and described with respect to directions shown in the accompanying drawings. In contrast, when an element is referred to as being “directly connected with” another element, there are no intervening elements present. Unless “immediately” or “directly” is used when describing location relationship, for example, “on,” “above,” “under,” “next,” etc., one or more other elements may be also present.

Throughout the disclosure, each component can be provided as a single one or a plurality of ones, unless explicitly stated to the contrary. Terms such as “include” or “has” are used herein and should be understood that they are intended to indicate an existence of several components, functions or steps, disclosed in the specification, and it is also understood that greater or fewer components, functions, or steps may likewise be utilized. A singular representation may include a plural representation unless it represents a definitely different meaning from the context. In understanding the components, it should be understood as including the error range even if there is no separate explicit description.

Features of various embodiments may be partially or entirely combined with each other, and various connections and driving are possible. Also, embodiments may be implemented independently or implemented in a related relationship.

Hereinafter, a display device according to the accompanying drawings and embodiments will be described as follows.

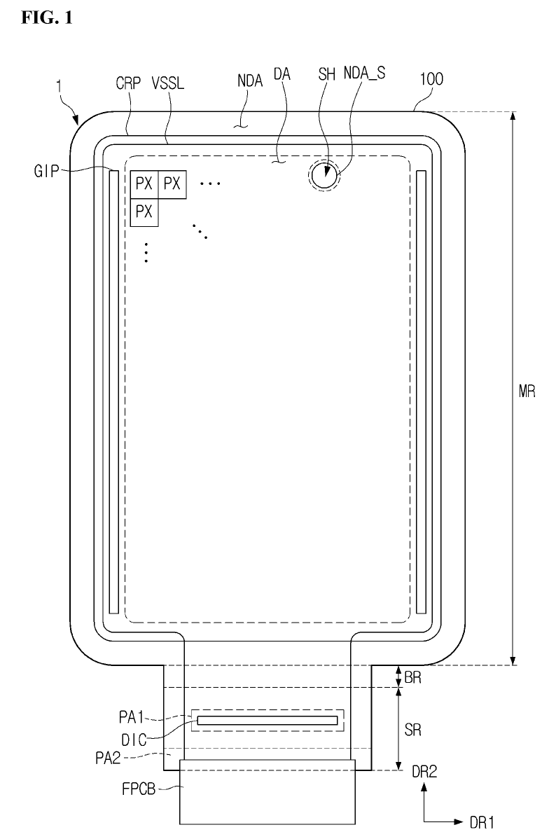

FIG. 1 is a plan view showing a display device according to one embodiment;

Referring to FIG. 1, a display device 1 according to one embodiment may include a display panel 100. The display panel 100 may include a display area DA including a plurality of pixels PX; and a non-display area NDA adjacent to the display area DA. The display area DA may have a rectangular shape. However, the embodiments are not limited thereto and the planar shape of the display area DA may be a square, a circle, an ellipse, or other polygonal shape. For example, the display area (DA) may be a rectangular shape with rounded corners (or curved surface), but the embodiments are not limited thereto, and may also be a rectangular shape with sharp corners.

In the embodiments, the first direction DR1 and the second direction DR2 are different directions and represent directions that intersect each other, for example, directions that intersect perpendicularly on a plane. In FIG. 1, the first direction DR1 may be generally the same as the extension direction of the short sides of the display panel 100, and the second direction DR2 may be the same as the extension direction of the long sides of the display panel 100. However, it should be understood that the directions mentioned in the embodiment refer to relative directions, and the embodiments are not limited to the mentioned directions.

The display area DA may include short sides extending along the first direction DR1 and long sides extending along the second direction DR2. A non-display area NDA may surround the display area DA. The non-display area NDA can be arranged on one side of the display area DA in the first direction DR1, the other side of the first direction DR1, one side of the second direction DR2, and the other side of the second direction DR2.

The display panel 100 may include a sensor non-display area NDA_S, and a sensor hole SH surrounded by the sensor non-display area NDA_S. the sensor hole SH may be surrounded by the display area DA on a plane. One sensor hole SH may be provided as shown in FIG. 1 but the embodiments are not limited thereto. For example, two sensor holes SH may be provided, and each of the two sensor holes SH may include a sensor hole in which an infrared sensor is arranged and a sensor hole in which a camera sensor is arranged, but the embodiments are not limited thereto.

A gate driver GIP may be placed on each of the non-display area NDA located on one side of the first direction DR1 of the display area DA and the other side of the first direction DR1. A low voltage line VSSL may be arranged outside the gate driver GIP on the non-display area NDA. For example, as shown in FIG. 1, the low voltage line VSSL may extend from the printed circuit board FPCB, pass through the sub-region SR and the bending region BR, be positioned outside the gate driver GIP on the non-display area ND, and be arranged to surround the display area DA.

The non-display area NDA located on the lower side of the second direction DR2 of the display area DA can extend further in the downward direction of the second direction DR2 from the center of the other side of the second direction DR2 of the display area DA. In the central portion of the lower side of the second direction DR2 of the display area DA, the width in the first direction DR1 of the non-display area NDA extending further in the lower side of the second direction DR2 may be smaller than the width in the first direction DR1 of the non-display area NDA adjacent to the lower side of the second direction DR2 of the display area DA.

The display device 1 may include a main-region MR, a sub-region SR, and a bending region BR between the main-region MR and the sub-region SR and display area DA and the non-display area NDA surrounding four sides of the display area DA, which are described above, may form the main-region MR. In the central portion of the lower side of the second direction DR of the display area DA, a portion extending further in the lower direction of the second direction DR2 can form a bending region BR and a sub-region SR. The bending region BR may be disposed between the sub-region SR and the main-region MR. the sub-region SR may include a first pad area PA1 and a second pad area PA2 disposed at the lower end of the second direction DR2 of the sub-region SR. The display device 1 may further include a data driver DIC and a printed circuit board FPCB. The data driver DIC may be disposed in the first pad area PA1 and the printed circuit board FPCB may be attached to the second pad area PA2. In the first pad area PA1 and the second pad area PA2, multiple pads connected to the data driver DIC and the printed circuit board FPCB may be arranged. For example, the data driver DIC may be formed as, for example, a driver chip IC, but the embodiments are not limited thereto. In one embodiment, the data driver DIC is arranged in the form of a chip on plastic directly mounted on the display panel 100, but the embodiments are not limited thereto and may be arranged in the form of a chip on glass or a chip on film.

The display panel 100 according to one embodiment may further include a crack detecting pattern CRP. The low voltage line VSSL may be arranged between the display area DA and the crack detecting pattern CRP. The crack detecting pattern CRP may be arranged to completely surround the display area DA, as shown in FIG. 1. For example, the crack detection pattern CRP may be placed between the clad part CLP and the low voltage line VSSL. However, the embodiments of the present specification are not limited thereto, and the crack detecting pattern CRP may not be placed in some of the non-display area NDA on the other side of the second direction DR2 of the display area DA. In some embodiments, the crack detection pattern may be formed as a circuit in a non-display area NDA on one side of the second direction DR2 of the display area DA. In this case, the crack detection pattern may be composed of two wires, and the wire of one crack detection pattern may be located on the left side (or the lower side of the second direction DR2) and the wire of the other crack detection pattern may be located on the right side (or one side of the second direction DR2).

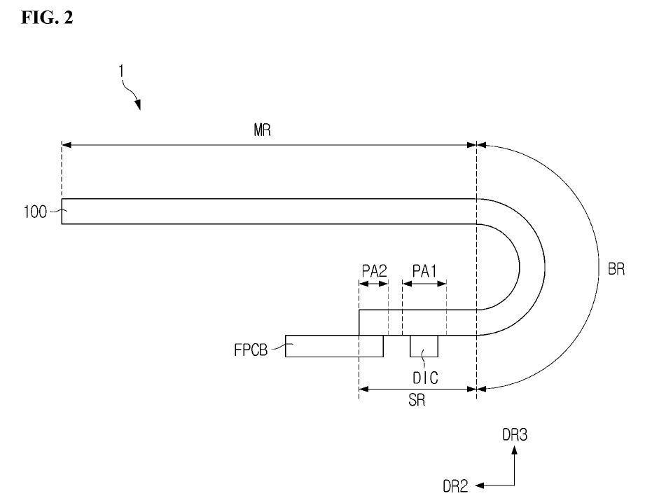

FIG. 2 is a cross-sectional view showing the state where a display shown in FIG. 1 is bent.

Referring to FIG. 2, the bending region BR of the display panel 100 of the display device 1 according to one embodiment may be bent in the thickness direction DR3 (or the lower direction with respect to the third direction). Due to this, the main-region MR and the sub-region SR can overlap in the thickness direction DR3. The display panel 100 can be bent in such a way that the lower surface of the main-region MR and the upper surface of the sub-region SR face each other. The printed circuit board FPCB can be attached to an end of the sub-region SR.

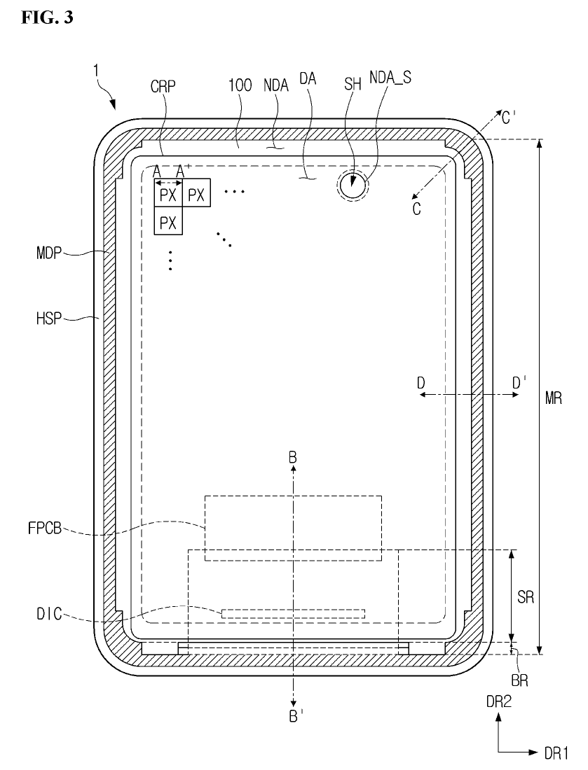

FIG. 3 is a plane view showing the state where a display shown in FIG. 1 is bent.

Referring to FIG. 3, the display device 1 may further include a mold MDP and a housing HSP.

The bending region BR of the display panel 100 is bent so that the sub-region SR may overlap the main-region MR. The printed circuit board FPCB and the data driver DIC each may overlap the main-region MR.

The mold MDP may be placed on the outside of the display panel 100. The mold MDP may be placed along the edge of the bent display panel 100. The mold MDP can be in direct contact with the side of the bent display panel 100. The mold MDP can include an organic material. As shown in FIG. 3, the mold MDP can include an organic material that repeats shrinkage and expansion based on heat.

A housing HSP may be placed on the outside of the display panel 100 and the mold MDP. The housing HSP may be placed along the edge of the mold MDP.

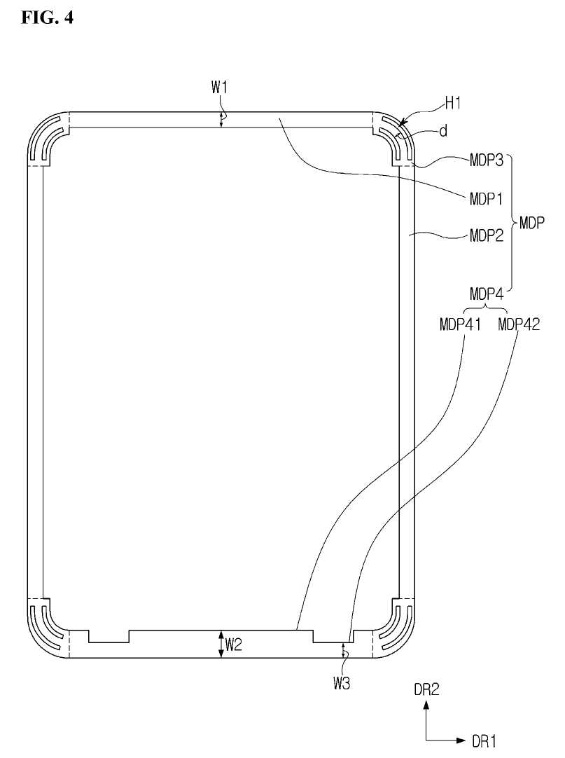

FIG. 4 is a plan view of a mold part shown in FIG. 3.

Referring to FIGS. 3 and 4, the mold part MDP may include first to fourth mold part MDP4. The first mold part MDP1 may be positioned on the upper short side of the display panel in the second direction DR2. The second mold part MDP2 may be positioned on the left-right short side of the display panel 100. The third mold part MDP3 may be positioned at the corner of the display panel 100, and the fourth mold part MDP4 may be positioned on the lower short side of the display panel 100 in the second direction DR2.

The first mold part MDP1 may have a first width W1 along the second direction DR2. The fourth mold portion MDP4 includes a first portion MDP41 having a second width W2 and a second portion MDP42 having a third width W3. Here, the second width W2 can be greater than the third width W3. The first portion MDP41 and the second portion MDP42 may be repeatedly arranged in the first direction DR1, but the embodiments are not limited thereto.

A first pattern H1 may be arranged in the third mold portion MDP3. The first pattern H1 may be provided in plural, for example, two or three or more patterns, but the embodiments are not limited thereto. Since the third mold portion MDP3 includes a curved shape like a corner of the display panel 100, the first pattern H1 of the third mold portion MDP3 may also have a line shape extended in a curved shape, but the embodiments are not limited thereto. Adjacent first patterns H1 are spaced apart from each other and can be spaced apart with a predetermined separation distance d. Adjacent first patterns H1 can be spaced apart in either direction between the first direction DR1 and the second direction DR2.

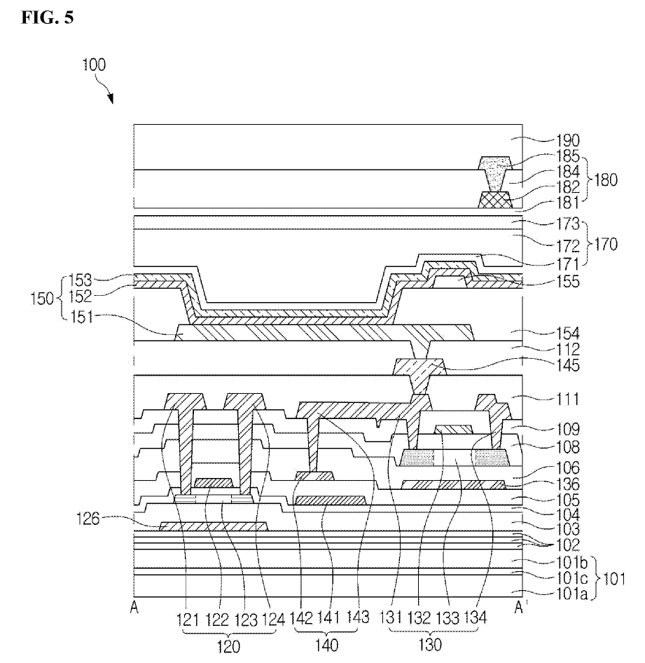

FIG. 5 is a cross-sectional view cut along A-A’ of FIG. 3. Referring to FIG. 5, the display panel 100 may include a substrate 101, a buffer layer 102, a first thin film transistor 120, a second thin film transistor 130, a storage electrode 140, a light emitting part 150, an encapsulating part 170, a touch part 180, and an upper organic layer 190.

The substrate 101 may include one or more plastic materials. For example, the substrate 101 may be a multi-substrate including a plurality of plastic materials such as polyimide, but the embodiments are not limited thereto. For example, the substrate 101 may include a first substrate portion 101a, a second substrate portion 101b, each including a plastic material, and a third substrate portion 101c including an inorganic material between the first substrate portion 101a and the second substrate portion 101b, but the embodiments are not limited thereto.

The buffer layer 102 may be placed on the substrate 101 The buffer layer 102 may minimize or delay the diffusion of moisture or oxygen penetrating the substrate 101. The buffer layer 102 may be formed by alternately stacking silicon nitride (SiNx) and silicon oxide (SiOx) at least once, but the embodiments are not limited thereto.

A first light-blocking layer 126 may be disposed on the buffer layer 102. The first light blocking layer 126 may be configured to prevent external light from transmitting to the first semiconductor layer 123 of the first thin film transistor 120. For example, the first semiconductor layer 123 may be disposed to overlap the first light blocking layer 126.

The first insulating layer 103 may be arranged on the first light blocking layer 102. The first insulating layer 103 may be made of the same material as the buffer layer 102, but the embodiments are not limited thereto.

The first thin film transistor 120 may be placed on the first insulating layer 103. The first thin film transistor 120 may include a first source electrode 121, a first gate electrode 122, a first semiconductor layer 123, and a first drain electrode 124.

The first semiconductor layer 123 may be disposed on the first insulating layer 103. The first semiconductor layer 123 may include a metal oxide semiconductor such as IGZO (Indium-Gallium-Zinc Oxide), a silicon-based semiconductor material such as amorphous silicon or polycrystalline silicon, but the embodiments are not limited thereto. The first semiconductor layer 123 may include a channel area, a source area, and a drain area.

The second insulating layer 104 may be arranged on the first semiconductor layer 123. The second insulating layer 104 may be made of the same material as the first insulating layer 103, but the embodiments are not limited thereto.

The first gate electrode 122 may be arranged on the second insulating layer 104. The first gate electrode 122 may be arranged on the second insulating layer 104 so as to overlap with the channel region of the first semiconductor layer 123. The first gate electrode 122 may be composed of a single layer or multiple layers including molybdenum (Mo), copper (Cu), titanium (Ti), aluminum (Al), chromium (Cr), gold (Au), nickel (Ni), neodymium (Nd), or compounds thereof, but the embodiments are not limited thereto. The first gate electrode 122 may be arranged together with a gate line.

A third insulating layer 105 may be placed on the first gate electrode 122. The third insulating layer 105 may be made of the same material as the first insulating layer 103 or the second insulating layer 104.

On the third insulating layer 105 may be disposed the first source electrode 121 and the first drain electrode.

The first source electrode 121 and the first drain electrode 124 can be electrically connected to the first semiconductor layer 123 through a contact hole. The first source electrode 121 and the first drain electrode 124 can be formed of a metal material.

The first source electrode 121 and the first drain electrode 124 may be arranged together with the data line.

The storage electrode 140 may be placed apart from the first thin film transistor 120. The storage electrode 140 may include a first storage electrode 141, a second storage electrode 142, and a third storage electrode 143.

The first storage electrode 141 may be arranged in the same layer with the same material as the first gate electrode 122, but the embodiments are not limited thereto.

The second storage electrode 142 may be placed on the first storage electrode 141. The second storage electrode 142 may be placed on the third insulating layer 105, and a capacitance may be formed by using the third insulating layer 105 between the first storage electrode 141 and the second storage electrode 142 as a dielectric.

A second thin film transistor 130 may be placed spaced apart from the first thin film transistor 120 and the storage electrode 140. The second thin film transistor 130 may include a second source electrode 131, a second gate electrode 132, a second semiconductor layer 133, and a second drain electrode 134.

A second light-blocking layer 136 may be placed on the same layer as the second storage electrode 142.

The second semiconductor layer 133 can be arranged to overlap the second light-blocking layer 136.

A fourth insulating layer 106 may be placed on the second light-blocking layer 136. The fourth insulating layer 106 may be the same material as the first insulating layer 103, the second insulating layer 104, or the third insulating layer 105, but the embodiments are not limited thereto.

A second semiconductor layer 133 may be arranged on the fourth insulating layer 106. The second semiconductor layer 133 may include a source area, a drain area, and a channel area between the source area and the drain area.

The second semiconductor layer 133 may include a metal oxide semiconductor such as IGZO (Indium-Gallium-Zinc Oxide), a silicon-based semiconductor material such as amorphous silicon or polycrystalline silicon, but the embodiments are not limited thereto.

A fifth insulating layer 108 may be arranged on the second semiconductor layer 133. The fifth insulating layer 108 may be the same material as the first insulating layer 103, the second insulating layer 104, the third insulating layer 105, or the fourth insulating layer 106, but the embodiments are not limited thereto.

The second gate electrode 132 may be arranged on the fifth insulating layer 108.

The second gate electrode 132 may be made of the same material as the first gate electrode 122.

A sixth insulating layer 109 may be arranged on the second gate electrode 132. The sixth insulating layer 109 may be the same material as the first insulating layer 103, the second insulating layer 104, the third insulating layer 105, the fourth insulating layer 106, or the fifth insulating layer 108, but the embodiments are not limited thereto.

The first source electrode 121, the first drain electrode 124, the third storage electrode 143, the second source electrode 131, and the second drain electrode 134 may be arranged on the sixth insulating layer 109.

The second source electrode 131 and the second drain electrode 134 may be made of the same material as the first source electrode 121 and the first drain electrode 124, and may be arranged in the same layer.

The first thin film transistor 120 may be a driving transistor, and the second thin film transistor 130 may be a switching transistor, but the embodiments are not limited thereto.

A first protective layer 111 may be placed on the first source electrode 121 and the first drain electrode 124.

The first protective layer 111 can planarize the upper portion of the first thin film transistor 120 and protect the first thin film transistor 120. The first protective layer 111 can be made of an organic material.

A second protective layer 112 may be placed on the first protective layer 111. The second protective layer 112 may be formed of the same material as the first protective layer 111, but the embodiments are not limited thereto.

A connecting electrode 145 may be placed between the first protective layer 111 and the second protective layer 112.

The connecting electrode 145 can electrically connect the second thin film transistor 130 and the light emitting part 150.

The light-emitting part 150 may be placed on the second protective layer 112. The light-emitting part 150 may include an anode electrode 151, an organic layer 152, and a cathode electrode 153.

The anode electrode 151 may be arranged on the second protective layer 112. The anode electrode 151 may be electrically connected to the second thin film transistor 130 through a contact hole formed in the second protective layer 112. The anode electrode 151 may be a reflective electrode that reflects light, but the embodiments of the present specification are not limited thereto. The anode electrode 151 may include a highly reflective metal material such as a laminated structure of aluminum (Al) and titanium (Ti) (Ti/Al/Ti), a laminated structure of aluminum (Al) and ITO (ITO/Al/ITO), or an APC alloy, and may be formed of a single layer or multiple layers, but the embodiments of the present specification are not limited thereto.

An organic layer 152 may be disposed on the anode electrode 151. The organic layer 152 may include one or more light-emitting structures (or light-emitting elements or elements) laminated in the order or reverse order of the hole transport layer and the electron transport layer on the anode electrode 151. The organic layer 152 may be an organic light-emitting layer, an inorganic light-emitting layer, a quantum dot light-emitting layer, a micro light-emitting diode, or a micro mini light-emitting diode, but the embodiments are not limited thereto.

The cathode electrode 153 may be placed on the organic layer 152. The cathode electrode 153 may be a transparent electrode that transmits light, but the embodiments are not limited thereto. For example, the cathode electrode 153 may include a transparent conductive material such as ITO (Indium Tin Oxide) or IZO (Indium Zinc Oxide) or a metal that transmits visible light.

The bank 154 may be arranged to expose the anode electrode 151. The bank 154 may be arranged to define an opening (or a light-emitting area) of the sub-pixel and cover an edge portion (or a border portion) of the anode electrode 151. Each of the sub-pixels may include a red light-emitting area, a green light-emitting area, and a blue light-emitting area. For example, the sub-pixel may be a pixel, but is not limited to the term.

A spacer 155 may be further arranged on the bank 154.

The encapsulating part 170 may be arranged on the bank 154 or the light-emitting part 150. The encapsulating part 170 may include one or more insulating layers. For example, the encapsulating part 170 may include a first encapsulating layer 171, a second encapsulating layer 172 on the first encapsulating layer 171, and a third encapsulating layer 173 on the second encapsulating layer 172. The encapsulating part 170 may include one or more inorganic material layers and one or more organic material layers. For example, the first encapsulating layer 171 and the third encapsulating layer 173 may include an inorganic material, and the second encapsulating layer 172 may include an organic material.

A touch buffer layer 181 may be arranged on the encapsulating part 170. For example, the touch buffer layer 181 may be arranged on the third encapsulating layer 173. The touch buffer layer 181 may be made of the same material as the buffer layer 102. A first touch conductive layer may be placed on the buffer layer 181. A touch insulating layer 184 may be disposed on the first touch conductive layer. The touch insulating layer 184 may prevent a short between touch electrodes. The touch insulating layer 184 may include an organic material or an inorganic material, but the embodiments are not limited thereto. It is exemplified in FIG. 5 that the touch insulating layer 184 includes an organic material, but the embodiments are not limited thereto. A second touch conductive layer 185 may be disposed on the touch insulating layer 184.

The first touch conductive layer may include a second touch electrode 182, and the second touch conductive layer may include a first touch electrode 185.

The second touch electrode 182 may be electrically connected to the first touch electrode 185 through a contact hole formed in the touch insulating layer 184.

The first touch electrode 185 and the second touch electrode 182 may include metal.

An upper organic layer 190 may be disposed on the touch part 180, but the embodiments are not limited thereto.

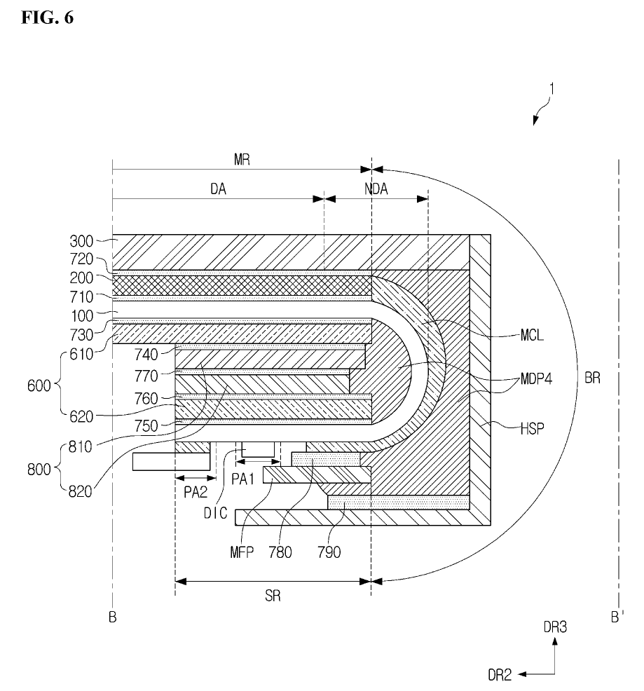

FIG. 6 is a cross-sectional view cut along B-B’ of FIG. 3.

Referring to FIGS. 5 and 6, the display device 1 may include a display panel 100, a planarizing layer 200, a cover layer 300, a back plate layer 600, a plate layer 800, a bonding layer 710, 720, 730, 740, 750, 760, 770, 780, and 890, a cover layer MCL, a mold MDP, a mold frame MFP, and a housing HSP.

The bending region BR of the display panel 100 has a curved shape and can be bent in the thickness direction. The main-region MR and the sub- region SR of the display panel 100 can overlap each other.

The polarizing layer 200 may be arranged on the main-region MR of the display panel 100. The polarizing layer 200 may polarize light emitted from the display panel 100 at a polarization angle. The polarizing layer 200 may emit light polarized at a polarization angle to the outside. The polarizing layer 200 may include a function of blocking reflection of light except for light polarized at a polarization angle among external light. The polarizing layer 200 may include a first phase delay layer, a second phase delay layer on the first phase delay layer, and a polarizing layer on the second phase delay layer. In FIGS. 5 and 6, the polarizing layer 200 and the display panel 100 are shown as being separate from each other, but the embodiments are not limited thereto. In some embodiments, the planarizing layer 200 may be omitted and a color filter may be provided.

The cover layer 300 may be arranged on the polarizing layer 200. The cover layer 300 may be formed of a glass material including glass or quartz, but the embodiments are not limited thereto, and may be formed of a plastic material. The cover layer 300 may be arranged on the display panel 100 to protect members arranged under the cover layer 300 from the outside. The cover layer 300 may be a cover layer formed by chemical strengthening, but the embodiments are not limited thereto. The cover layer 300 may be a cover window, a window cover, or a cover member, but the embodiments are not limited thereto.

The cover layer 300 can protect the components placed under the cover layer 300 from the outside, but as described above, since the cover layer 300 is formed of a glass material, the cover layer 300 may be damaged by an external force, creating glass fragments. The glass fragments may fly to the outside of the display device 1. According to an embodiment of the present disclosure, in order to prevent flying of glass fragments due to damage to the cover layer 300 or to improve the durability of the cover layer 300, the display device 1 may further include at least one other layer (not shown in FIG. 6) on the cover layer 300. For example, the display device 1 may further include a film layer (not shown in FIG. 6) or a coating layer (not shown in FIG. 6) on the cover layer 300, but the embodiments are not limited thereto.

The lateral surface of the cover layer 300 may protrude outwardly more than the lateral surface of the display panel 100. For example, the lateral surface of the cover layer 300 may protrude outwardly more than the end surface of the bending region BR of the display panel 100, but the embodiments are not limited thereto.

The backplate layer 600 may be arranged at the bottom of the display panel 100. The backplate layer 600 may be arranged at the bottom of the display panel 100 to support the display panel 100. The backplate layer 600 may include a material capable of supporting the display panel 100. For example, the backplate layer 600 may include polyethylene terephthalate (PET), polyimide (PI), or polycarbonate (PC), but the embodiments are not limited thereto. The backplate layer 600 may keep the curvature of the display panel 100 constant when the display device 1 is folded, and may suppress wrinkles occurring on the upper surface of the display panel 100.

The backplate layer 600 may include a first backplate layer 610 on the main-region MR and a second backplate layer 620 on the sub- region SR. The first backplate layer 610 may be disposed between the main-region MR of the display panel 100 and the plate layer 800, and the second backplate layer 620 may be disposed between the sub- region SR of the display panel 100 and the plate layer 800. The backplate layer 600 may not be disposed on the bending region BR.

The plate layer 800 may be placed between the first backplate layer 610 and the second backplate layer 620. The plate layer 800 may include metal. For example, the plate layer 800 may include stainless steel, but the embodiments are not limited thereto. The plate layer 800 may include a first plate layer 810 between the first back plate layer 610 and the second back plate layer 620, and a second plate layer 820 between the first plate layer 810 and the second plate layer 620.

Additional bonding layers may be arranged between the above-described members 100, 200, 300, 600, 610, 620, 810 and 820. The bonding layers may include a first bonding layer 710, a second bonding layer 720, a third bonding layer 730, a fourth bonding layer 740, a fifth bonding layer 750, a sixth bonding layer 760, and a seventh bonding layer 770.

The first bonding layer 710 may be placed between the display panel 100 and the polarizing layer 200. The first bonding layer 710 may connect or bond the display panel 100 and the polarizing layer 200.

The second bonding layer 720 may be placed between the polarizing layer 200 and the cover layer 300. The second bonding layer 720 may connect or bond the polarizing layer 200 and the cover layer 300.

The third bonding layer 730 may be placed between the first backplate layer 610 and the display panel 100. The third bonding layer 730 may connect or bond the first backplate layer 610 and the display panel 100.

The fourth bonding layer 740 may be placed between the first backplate layer 610 and the first plate layer 810. The fourth bonding layer 740 may connect or bond the first backplate layer 610 and the first plate layer 810.

The fifth bonding layer 750 may be arranged between the second back plate layer 620 and the sub-region SR. The fifth bonding layer 750 may connect or bond the second back plate layer 620 and the display panel 100.

The sixth bonding layer 760 may be arranged between the second back plate layer 620 and the second plate layer 820. The sixth bonding layer 760 may connect or bond the second back plate layer 620 and the second plate layer 820.

The seventh bonding layer 770 may be disposed between the first plate layer 810 and the second plate layer 820. The seventh bonding layer 770 may connect or bond the first plate layer 810 and the second plate layer 820.

The eighth bonding layer 780 may be disposed between the mold frame MFP and the cover layer MCL. The eighth bonding layer 780 may connect or bond the mold frame MFP and the cover layer MCL.

The ninth bonding layer 790 may be disposed between the fourth mold part MDP4(or mold part) and the housing HSP. The ninth bonding layer 790 may connect or bond the mold part MDP and the housing HSP.

The first bonding layer 710 and the second bonding layer 720 may each include a transparent adhesive, but the embodiments are not limited thereto. For example, the transparent adhesive may be a transparent resin (OCR) or a transparent adhesive (OCA), but the embodiments are not limited thereto. The third bonding layer 730, the fourth bonding layer 740, the fifth bonding layer 750, the sixth bonding layer 760, the seventh bonding layer 770, the eighth bonding layer 780, and the ninth bonding layer 790 may each include a pressure sensitive adhesive (PSA), but the embodiments are not limited thereto.

The cover layer MCL may be arranged on one side of the bending region BR of the display panel 100. The cover layer MCL includes a plastic material and may be coated on one side of the bending region BR of the display panel 100 to cover the bending region BR of the display panel 100. A link line may be arranged on the bending region BR. The cover layer MCL may protect the link line LL from external impact while preventing moisture penetration into the link line. In addition, the cover layer MCL may serve to position the link line in a neutral plane when the bending region BR of the display panel 100 is bent into a curved shape having a constant radius of curvature. Within the bending region BR, a neutral plane is formed where the tensile force and the compressive force are zero, and the link line is positioned on the neutral plane, so that when the display panel 100 is bent, the link line receives a bending stress of zero, and thus the display panel 100 can be bent without being damaged by the bending stress.

The cover layer MCL can be in contact with the lateral surfaces of the polarizing layer 200 and the first bonding layer 710. The cover layer MCL can partially extend to the sub-region SR. On the sub-region SR, the cover layer MCL can be bonded to the mold frame MFP through the eighth bonding layer 780.

The data driver DIC may be placed in a first pad area PA1 of the sub-region (SR), and the printed circuit board FPCB may be placed in a second pad area PA2. The printed circuit board FPCB may be electrically connected to pads on the display panel 100 through an anisotropic conductive film ACF. The cover layer MCL may not overlap with the data driver DIC, but the embodiments are not limited thereto.

The mold frame MFP may be placed under the cover layer MCL.

The fourth mold part MDP4 (or mold part) may be placed on the cover layer MCL. The fourth mold part MDP4 (or mold part) may cover the outer surface of the bending region BR of the display panel 100. For example, it may be in direct contact with the cover layer MCL, the lower surface of the cover layer 300, the lateral surface of the fifth bonding layer 750, the upper surface, the lateral surface, and the lower surface of the mold frame MFP. The fourth mold part MDP4 may also be in contact with the inner surface of the housing HSP. The fourth mold part MDP4 may also be placed on the inner side of the bending region BR. The fourth mold MDP4 may be in contact with the inner surface of the bending region BR, the lateral surfaces of the first and second backplate layers 610 and 620, and the lateral surfaces of the first and second plate layers 810 and 820.

The housing HSP may be placed on the outermost side of the display device 1. A portion of the housing HSP extending in the thickness direction (or the third direction DR3) may be in direct contact with the cover layer 300 and the fourth mold part MDP4. A portion of the housing HSP extending in the second direction DR2 may be bonded to the fourth mold part MDP4 through the ninth bonding layer 790.

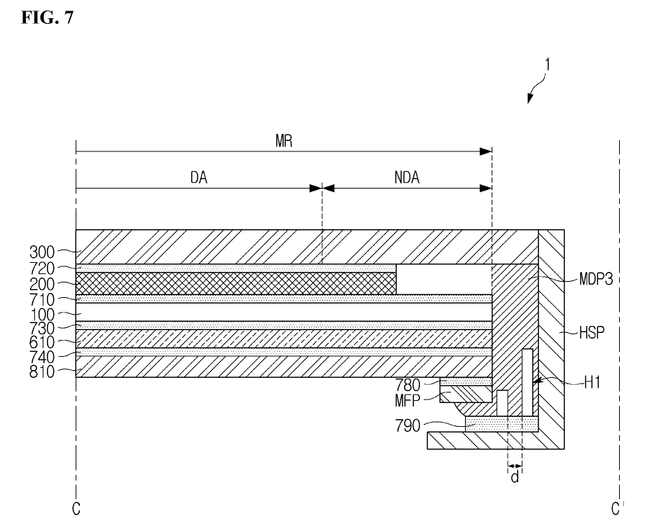

FIG. 7 is a cross-sectional view cut along C-C’ of FIG. 3. FIG. 7 shows the main-region MR including the display area DA and the non-display area NDA. FIG. 7 exemplifies a cross-sectional view showing the right corner region of the display device 1. The cross-sectional view of the right region of the display device 1 may be substantially identical to the cross-sectional views of the left corner region of the display device 1.

Referring to FIGS. 4 to 7, the third mold part MDP3 (or mold part) may be in direct contact with the lateral surface of the display panel 100, the lateral surface of the first backplate layer 610, and the lateral surface of the first plate layer 810. The third mold part MDP3 may be in direct contact with the lateral surface and lower surface of the mold frame MFP. The third mold part MDP3 may be coupled to the housing HSP through the ninth bonding layer 790. The third mold part MDP3 may become in contact with the lower surface of the cover layer 300 and the inner surface of the housing HSP.

Meanwhile, a first pattern H1 may be disposed in the third mold part MDP3. The first pattern H1 may be formed by recessing from the lower surface of the third mold part MDP3, and the first pattern H1 may be a recess or slit. For example, if the first pattern H1 is a recess, the first pattern H1 may not penetrate the third mold part MDP3 completely. If the first pattern H1 is a slit, the first pattern H1 may overlay the cover layer 300.

The first pattern H1 will be described in detail later.

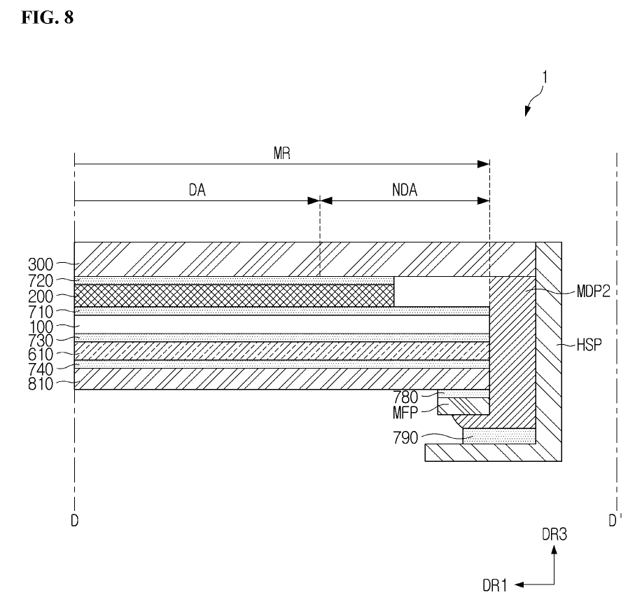

FIG. 8 is a cross-sectional view cut along D-D’ of FIG. 3. FIG. 8 shows the main-region MR including the display area DA and the non-display area NDA. FIG. 8 shows a cross-sectional view of the right area (or one short side in the first direction DR) of the display device 1. The cross-sectional view of the right area of the display device 1 may be substantially identical to the cross-sectional views of the left area and the upper area of the display device 1.

Referring to FIGS. 4 to 8, the second mold part MDP2 (or mold part) can be in direct contact with the lateral surface of the display panel 100, the lateral surface of the first back plate layer 610, and the lateral surface of the first plate layer 810. The second mold part MDP2 can be in direct contact with the lateral surface and the lower surface of the mold frame MFP. The second mold part MDP2 can be bonded to the housing HSP through the ninth bonding layer 790. The second mold part MDP2 can be in contact with the lower surface of the cover layer 300 and the inner surface of the housing HSP. Unlike the third mold part MDP3, the second mold part MDP2 may not include a pattern.

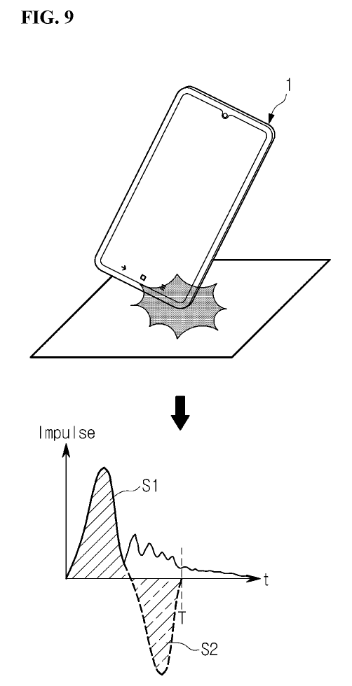

FIG. 9 illustrates a display device according to one embodiment being dropped.

Referring to FIG. 9, when the display device 1 is dropped, impulse may be applied to the display device 1. In FIG. 9, only the case where the display device 1 is dropped is exemplified, but an impulse may also occur when an external impulse is applied to the display device 1. FIG. 9 expresses the amount of impulse applied to the display device 1 over time. For example, the impulse may have a positive value, a first impulse with a first area S1, and a second impulse with a lower level after the first impulse. Meanwhile, the shape of the impulse with the first area S1 only shows about a half cycle, but if the shape of the impulse with the first area S1 is virtually increased to one cycle, the shape of the impulse with the second area S2 can be obtained. Through this, the period T of the shock wave applied to the display device 1 can be derived. In addition, the frequency (Hz) of the shock wave can be derived through the period T of the shock wave. The separation distance d between the first patterns H1 described above in FIG. 7 can be designed based on the calculated period T of the shock wave and the frequency (Hz) of the shock wave.

Furthermore, the material properties of the mold part (MDP, see FIG. 4) can also be considered to design the separation distance d. Based on the travel speed of the shock wave within the mold part MDP (e.g., related to the density of the mold part MDP and the frequency Hz of the shock wave, the length of the shock wave to satisfy one wavelength of the shock wave within the mold part MDP can be derived.

The distance (d) between the first patterns H1 according to one embodiment may be smaller than the length of the shock wave to satisfy one wavelength of the shock wave within the third mold part MDP3. In this case, the shock wave applied from the outside of the third mold part MDP3 may be blocked (or intercepted) in the first pattern H1 or the separation space between the first patterns H1.

Therefore, external impact applied to the mold part MDP is not transmitted to the display panel, thereby preventing the reliability of the display panel from being deteriorated.

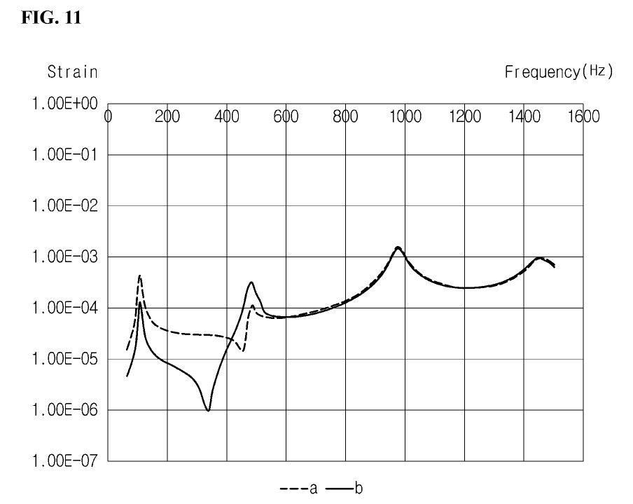

FIG. 11 is a graph showing that the shock of the display device is improved. The horizontal axis of FIG. 11 represents frequency Hz, and the vertical axis represents strain. Sample a may be a display device where the mold portion lacks the first pattern H1 described above, and sample b may be a display device where the mold part MDP includes the first pattern H1 described above.

The frequency of the shock wave described in FIG. 9 may be, for example, about 200 Hz to about 400 Hz. As shown in FIG. 11, it can be confirmed that the strain of sample b is lower than that of sample a at about 200 Hz to about 400 Hz.

According to the display device according to one embodiment (1, see FIG. 1), as described above, an external shock applied to the mold part MDP is not transmitted to the display panel (100, see FIG. 1), thereby preventing the reliability of the display panel from being deteriorated.

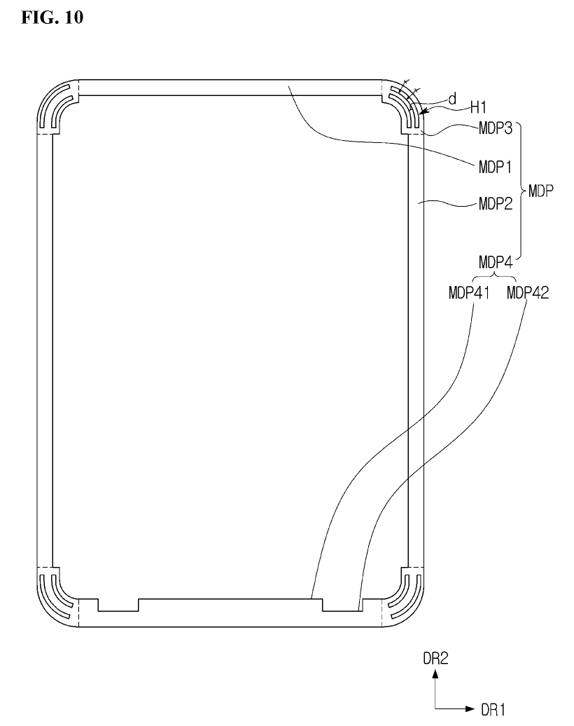

Referring again to FIG. 10, in addition, the mold part MDP may undergo thermal expansion in a high temperature environment. In particular, since the third mold part MDP3 is located at a corner, stress may be concentrated on the third mold part MDP3 during thermal expansion. However, in the display device according to one embodiment, since the first pattern H1 is arranged in the third mold part MDP3, even if the third mold part MDP3 expands, the third mold part MDP3 can fill the first pattern H1, so that stress concentration in the third mold part MDP3 can be alleviated.

Hereinafter, a display according to other embodiments will be described. In the embodiments below, detailed descriptions or repeated descriptions of the drawing numeral references or configurations described in FIGS. 1 to 11 will be omitted.

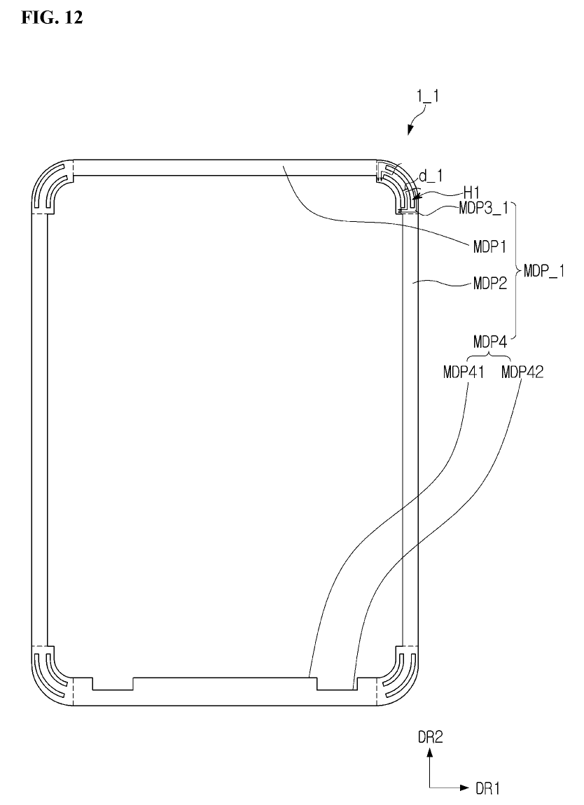

FIG. 12 is a plan view of a mold part according to another embodiment.

Referring to FIG. 12, according to the present embodiment, the mold part MDP_1 includes a third mold part MDP3_1, and a separation distance d_1 between the first patterns H1 of the third mold part MDP3_1 may be greater than a length of a shock wave to satisfy one wavelength of the shock wave within the third mold part MDP3_1. In this case, a shock wave applied from an outer portion of the third mold part MDP3_1 may bypass an adjacent first pattern H1 or a distant first pattern H1, and thus, the shock may be alleviated.

Other detailed descriptions are omitted as they are described above in FIG. 10.

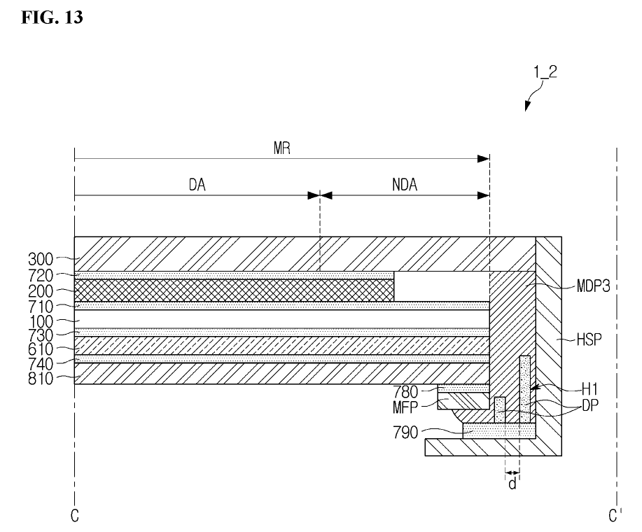

FIG. 13 is a cross-sectional view of a display device according to another embodiment.

Referring to FIG. 13, the first pattern H1 of the display device 1_2 according to the present embodiment is different from the display device 1 according to FIG. 7 in that a buffer part DP is further arranged.

More specifically, the display device 1_2 may further include the buffer part DP that fills the first pattern H1. The mechanical properties of the buffer part DP and the mechanical properties of the third mold part MDP3 may be different from each other. The above mechanical properties may include impedance or density. The density of the buffer part DP may be smaller than the density of the third mold part MDP3. For example, the buffer part DP may include rubber or silicone, but the embodiments are not limited thereto.

According to this embodiment, the buffer part DP is arranged within the first pattern H1, and the mechanical properties of the buffer part DP and the mechanical properties of the third mold part MDP3 are different from each other, so that a shock wave applied from the outside can be attenuated at the boundary between the third mold part MDP3 and the buffer part DP.

Other detailed descriptions are omitted as they are described above in FIG. 7.

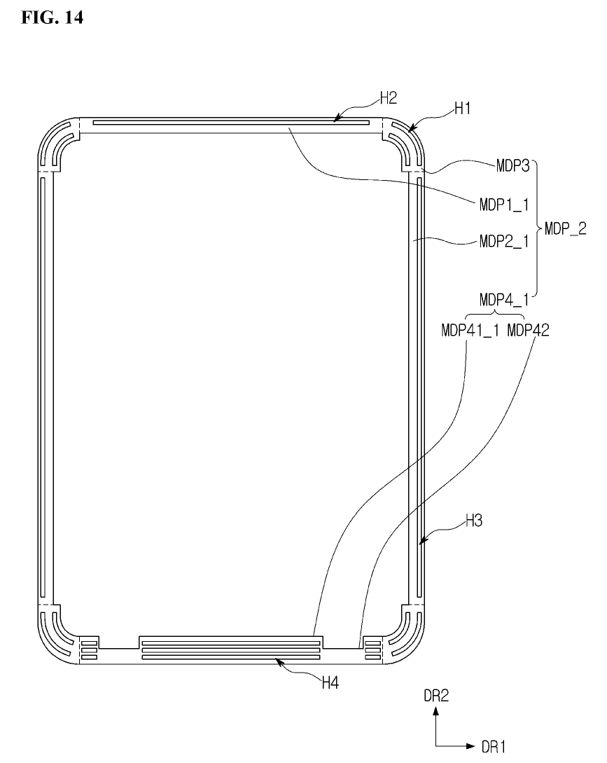

FIG. 14 is a plan view of a mold part according to another embodiment.

Referring to FIG. 14, the first mold part MDP1_1, the second mold part MDP2_1, and the fourth mold part MDP4_1 of the mold part MDP_2 according to this embodiment are different from the mold part MDP according to FIG. 10 in that they each include patterns H2, H3, and H4.

More specifically, the first mold part MDP1_1 may include a second pattern H2, the second mold part MDP2_1 may include a third pattern H3, and the fourth mold part MDP4_1 may include a fourth pattern H4.

The second pattern H2 can extend along the first direction DR1, the third pattern H3 can extend along the second direction DR2, and the fourth pattern H4 can extend along the first direction DR1. The fourth pattern H4 can be provided in multiple numbers. The multiple fourth patterns H4 can be spaced apart from each other in the second direction DR2.

In the mold part MDP_2 according to the present embodiment, the patterns H2, H3, and H4 can be arranged in other mold parts (the first mold part MDP1_1, the second mold part MDP2_1, and the fourth mold part MDP4_1) except for the third mold part MDP3. Therefore, there is an advantage in that the impact applied through the third mold part MDP3 can be alleviated through the patterns H2, H3, and H4 of the adjacent mold parts the first mold part (MDP1_1, the second mold part MDP2_1, and the fourth mold part MDP4_1).

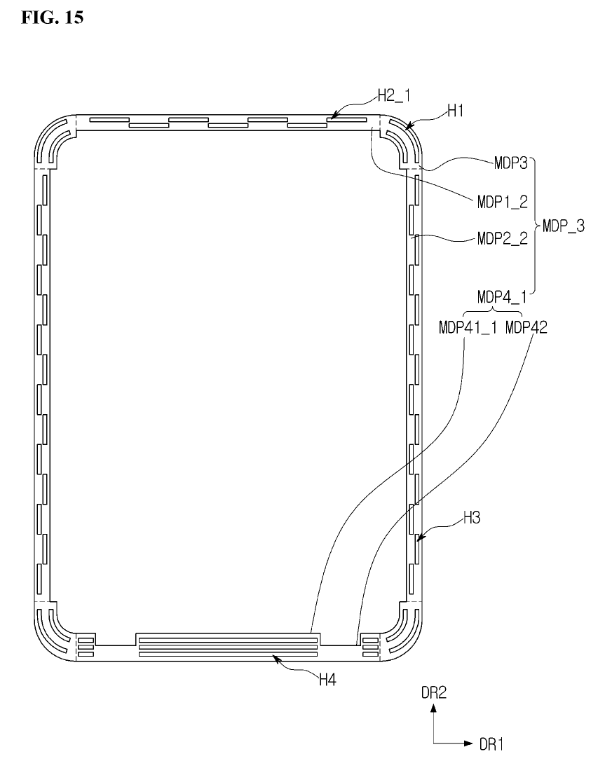

FIG. 15 is a plan view of a mold part according to a further embodiment.

Referring to FIG. 15, the patterns H2_1 and H3 of the first mold part MDP1_2 and the second mold part MDP2_2 of the mold part MDP_3 according to this embodiment are different from the mold part MDP_2 according to FIG. 14 in that there are multiple patterns.

More specifically, the second pattern H2_1 is provided in multiple numbers, and the multiple second patterns H2_1 can be arranged in a staggered manner along the first direction DR1 (or arranged in a zigzag manner). The third pattern H3 is provided in multiple numbers, and the multiple third patterns H3 can be arranged in a staggered manner along the second direction DR2 (or arranged in a zigzag manner).

Other detailed descriptions are omitted as they are described above in FIG. 14.

The display device according to various embodiments may be described as follows.

The display device according to the embodiments may include a display panel comprising a short side extending along a first direction, a long side extending along a second direction, and a corner at which the short side and the long side meet; and a mold part comprising a first mold part provided on the short side, a second mold part provided on the long side, and a third mold part provided at the corner. A first pattern that recesses the third mold part from the lower surface of the third mold part may be disposed in the third mold part.

The first pattern may be provided in a plurality, and the plurality of first patterns are spaced apart from each other.

In the display device according to the embodiments of the present disclosure, the plurality of first patterns may be spaced apart from each other diagonally along a direction intersecting the first direction and the second direction.

In the display device according to the embodiments of the present disclosure, the distance between the plurality of first patterns may be determined based on the density of the third mold part and the frequency of the shock wave within the third mold part.

The display device according to the embodiments of the present disclosure, may further include a buffer part disposed inside the first pattern. The density of the buffer part may be lower than the density of the third mold part.

In the display device according to the embodiments of the present disclosure, the buffer part may include rubber or silicone.

In the display device according to the embodiments of the present disclosure, a second pattern extending along the first direction may be disposed in the first mold part, and a third pattern extending along the second direction may be disposed in the second mold part.

In the display device according to the embodiments of the present disclosure, the second pattern may be provided in a plurality and the third pattern is provided in a plurality, and a first set of the plurality of second patterns may be arranged offset in a second direction from a second set of the plurality of second patterns, and a first set of the plurality of third patterns may be arranged offset in a first direction from a second set of the plurality of second patterns.

In the display device according to the embodiments of the present disclosure, the short side may be provided in a plurality and the first mold part is provided on one of the plural short sides, and the mold part may further include a fourth mold part provided on another one of the plurality of short sides and a fourth pattern extending along the first direction may be disposed in the fourth mold part.

In the display device according to the embodiments of the present disclosure, the fourth mold part may include a first portion and a second portion with a smaller width in the second direction than the first portion.

In the display device according to the embodiments of the present disclosure, the fourth pattern may be provided in the first portion, the fourth pattern may be provided in a plurality, and the plurality of fourth patterns may be spaced apart from each other in the second direction.

In the display device according to the embodiments of the present disclosure, the corner and the first pattern may include a curved surface.

In another aspect a display device according to the embodiments of the present disclosure may include a display panel comprising a main-region, a sub-region overlapping the main-region, and a bending region between the main-region and the sub-region; a mold part provided on the outside of the display panel; and a cover layer on the display play. A pattern may be disposed in the mold part on at least one of the sides and corners of the display panel, and the pattern may overlap the cover layer.

The display device according to the embodiments of the present disclosure may further include a first back plate layer on a lower surface of the display panel of the main-region; a second back plate between the display panel of the sub region and the first back plate layer; and a plate layer between the first back plate layer and the second back plate layer. The first back plate layer, the second back plate layer, and the plate layer may be in direct contact with the mold part.

In the display device according to the embodiments of the present disclosure, the display panel may include a short side extending along a first direction, a long side extending along a second direction, and a corner at which the short side and the long side meet, and the mold part may include a first mold part provided on the short side, a second mold part provided on the long side, and a third mold part provided at the corner,

In the display device according to the embodiments of the present disclosure, a first pattern may be disposed in the third mold part, the first pattern may be provided in a plurality, and the plurality of first patterns may be spaced apart from each other.

In the display device according to the embodiments of the present disclosure, the plurality of first patterns may be spaced apart from each other along a diagonal direction intersecting both the first direction and the second direction.

The space between the plurality of first patterns may be determined by considering the properties of the mold.

In the display device according to the embodiments of the present disclosure, a second pattern may be disposed in the first mold part, and a third pattern may be disposed in the second mold part.

In the display device according to the embodiments of the present disclosure, the second pattern may be provided in a plurality and the third pattern is provided in a plurality, and a first set of the plurality of second patterns may be arranged offset in a second direction from a second set of the plurality of second patterns, and a first set of the plurality of third patterns may be arranged offset in a first direction from a second set of the plurality of second patterns.

Although the present invention has been described with reference to the exemplified drawings, it is to be understood that the present invention is not limited to the embodiments and drawings disclosed in this specification, and those skilled in the art will appreciate that various modifications are possible without departing from the scope and spirit of the present invention. Further, although the operating effects according to the configuration of the present invention are not explicitly described while describing an embodiment of the present invention, it should be appreciated that predictable effects are also to be recognized by the configuration.

1. A display device comprising:
a display panel comprising a short side extending along a first direction, a long side extending along a second direction, and a corner at which the short side and the long side meet; and
a mold part comprising a first mold part provided on the short side, a second mold part provided on the long side, and a third mold part provided at the corner,
wherein a first pattern that recesses the third mold part from the lower surface of the third mold part is disposed in the third mold part.

2. The display device of claim 1, wherein the first pattern is provided in a plurality, and the plurality of first patterns are spaced apart from each other.

3. The display device of claim 2, wherein the plurality of first patterns are spaced apart from each other along a diagonal direction intersecting both the first direction and the second direction.

4. The display device of claim 2, wherein a distance between the plurality of first patterns is determined based on a density of the third mold part and a frequency of a shock wave within the third mold part.

5. The display device of claim 1, further comprising:
a buffer part disposed inside the first pattern,
wherein a density of the buffer part is lower than a density of the third mold part.

6. The display device of claim 5, wherein the buffer part includes rubber or silicone.

7. The display device of claim 1, wherein a second pattern extending along the first direction is disposed in the first mold part, and a third pattern extending along the second direction is disposed in the second mold part.

8. The display device of claim 7, wherein the second pattern is provided in a plurality and the third pattern is provided in a plurality, and a first set of the plurality of second patterns are arranged offset in the second direction from a second set of the plurality of second patterns, and a first set of the plurality of third patterns are arranged offset in the first direction from a second set of the plurality of third patterns.

9. The display device of claim 1, wherein the short side is provided in a plurality and the first mold part is provided on one of the plurality of short sides, and
the mold part further comprises a fourth mold part provided on another one of the plurality of short sides and a fourth pattern extending along the first direction is disposed in the fourth mold part.

10. The display device of claim 9, wherein the fourth mold part comprises a first portion and a second portion with a smaller width in the second direction than the first portion.

11. The display device of claim 10, wherein the fourth pattern is provided in the first portion, the fourth pattern is provided in a plurality, and the plurality of fourth patterns are spaced apart from each other in the second direction.

12. A display device comprising:
a display panel comprising a main-region, a sub-region overlapping the main-region and facing a part of the main-region, and a bending region between the main-region and the sub-region;
a mold part provided outside of the display panel; and
a cover layer on the display panel,
wherein the mold part includes a pattern that recesses the mold part from a surface of the mold part on at least one of a plurality of sides or corners of the display panel.

13. The display device of claim 12,
wherein the pattern overlaps the cover layer.

14. The display device of claim 12, further comprising:
a first back plate layer on a lower surface of the display panel of the main-region;
a second back plate between the display panel of the sub region and the first back plate layer; and
a plate layer between the first back plate layer and the second back plate layer,
wherein the first back plate layer, the second back plate layer, and the plate layer are in direct contact with the mold part.

15. The display device of claim 14, wherein the display panel comprises a short side extending along a first direction, a long side extending along a second direction, and a corner at which the short side and the long side meet, and
the mold part comprises a first mold part provided on the short side, a second mold part provided on the long side, and a third mold part provided at the corner.

16. The display device of claim 15, wherein a first pattern is disposed in the third mold part, the first pattern is provided in a plurality, and the plurality of first patterns are spaced apart from each other.

17. The display device of claim 16, wherein a distance between the plurality of first patterns is determined based on a density of the third mold part and a frequency of a shock wave within the third mold part.

18. The display device of claim 15, wherein a second pattern is disposed in the first mold part, and a third pattern is disposed in the second mold part.

19. The display device of claim 18, wherein the second pattern is provided in a plurality and the third pattern is provided in a plurality, and a first set of the plurality of second patterns are arranged offset in the second direction from a second set of the plurality of second patterns, and a first set of the plurality of third patterns are arranged offset in the first direction from a second set of the plurality of third patterns.

20. The display device of claim 12, further comprising:
a buffer part disposed inside the pattern,
wherein a density of the buffer part is lower than a density of the mold part.
